(19) United States
(12) Patent Application Publication
(10) Pub. No.: US 2003/0030060 A1
(43) Pub. Date: Feb. 13, 2003

(54) White semiconductor light-emitting device

(76) Inventor: Tadahiro Okazaki, Kyoto-shi (JP)

Correspondence Address: RADER FISHMAN & GRAUER PLLC, LION BUILDING, 1233 20TH STREET N.W., SUITE 501, WASHINGTON, DC, 20036, US

(21) Appl. No.: 10/206,977

(22) Filed: Jul. 30, 2002

(30) Foreign Application Priority Data
Aug. 7, 2001 (JP) 2001-239341

(51) Int. Cl. H01L 27/15; H01L 31/12; H01L 33/00

(52) U.S. Cl. 257/79

(57) ABSTRACT

In a white semiconductor light-emitting device, an ultraviolet light-emitting element 3 is used as a light-emitting element, and a phosphor layer 6 is formed that has a blue-light-emitting phosphor 61 and a yellow-light-emitting phosphor 62 mixedly diffused therein. This structure helps reduce variations in the produced white light among individual devices and enhance the productivity and light conversion efficiency of the device. For higher light conversion efficiency, the blue-light-emitting and yellow-light-emitting phosphors 61 and 62 are, preferably, phosphors that absorb ultraviolet light and emit blue and yellow light respectively.

### BACKGROUND OF THE INVENTION

1. Field of the Invention

The present invention relates to a white semiconductor light-emitting device, and more particularly to a white semiconductor light-emitting device provided with an ultraviolet light-emitting element and a phosphor.

2. Description of the Prior Art

In conventional white semiconductor light-emitting devices, on the light-emitting surface of a semiconductor light-emitting element that emits blue light, a layer containing a phosphor such as cerium-activated yttrium-aluminum-garnet (YAG) that absorbs blue light and emits yellow light is formed, so that the blue light from the semiconductor light-emitting element and the yellow light from the phosphor layer are mixed together to produce white light.

However, the peak wavelength of a blue-light semiconductor light-emitting element generally varies in a range of about 10 nm, and therefore the peak wavelength of the yellow light that a YAG phosphor layer emits by absorbing the blue light therefrom also varies, causing variations in the white light emitted from such a semiconductor light-emitting device.

A technique for reducing such variations in the white light emitted from a semiconductor light-emitting device is proposed, for example, in Japanese Patent Application Laid-Open No. 2000-183408. According to this publication, an ultraviolet light-emitting element is used as a light-emitting element, and, on top of the light-emitting surface of this light-emitting element, a layer of a phosphor that emits blue light and a layer of a phosphor that emits yellowish orange light are laid, so that the former layer absorbs ultraviolet light and emits blue light and simultaneously the latter layer absorbs blue light and emits yellowish orange light, with the thus obtained blue and yellowish orange light eventually mixed together to produce white light.

However, with this technique, which requires the formation of two phosphor layers, i.e., a blue-light phosphor layer and a yellowish-orange-light phosphor layer, it has been difficult to achieve satisfactorily high productivity. Moreover, with this technique, which converts light in two steps, i.e., from ultraviolet light to blue light and then from blue light to yellowish orange light, it has been impossible to achieve satisfactorily high light conversion efficiency.

### SUMMARY OF THE INVENTION

An object of the present invention is to provide a white semiconductor light-emitting device that can be fabricated with reduced variations in the white light it produces among individual devices and with high productivity.

Another object of the present invention is to provide a white semiconductor light-emitting device that offers satisfactorily high light conversion efficiency.

To achieve the above objects, according to the present invention, a white semiconductor light-emitting device is provided with an ultraviolet light-emitting element and a phosphor layer having a blue-light-emitting phosphor and a yellow-light-emitting phosphor mixedly diffused therein. With this structure, it is possible to reduce variations in the produced white light among individual devices, and to achieve high productivity.

For higher light conversion efficiency, it is preferable to use, as the blue-light-emitting and yellow-light-emitting phosphors, phosphors that absorb ultraviolet light and emit blue and yellow light respectively.

### BRIEF DESCRIPTION OF THE DRAWINGS

This and other objects and features of the present invention will become clear from the following description, taken in conjunction with the preferred embodiments with reference to the accompanying drawings in which:

FIG. 1 is a side sectional view showing an example of a chip-type semiconductor light-emitting device according to the invention;

FIG. 2 is a side sectional view showing another example of a chip-type semiconductor light-emitting device according to the invention;

FIGS. 3A and 3B are side sectional views showing other examples of chip-type semiconductor light-emitting devices according to the invention;

FIG. 4 is a side sectional view showing another example of a chip-type semiconductor light-emitting device according to the invention;

FIG. 5 is a side sectional view showing an example of a lead-type semiconductor light-emitting device according to the invention;

FIG. 6 is a side sectional view showing another example of a lead-type semiconductor light-emitting device according to the invention;

FIG. 7 is a side sectional view showing another example of a lead-type semiconductor light-emitting device according to the invention; and

FIG. 8 is a side sectional view showing another example of a lead-type semiconductor light-emitting device according to the invention.

### DESCRIPTION OF THE PREFERRED EMBODIMENTS

As a result of an intense study in search of a white semiconductor light-emitting device that can be fabricated with reduced variations in the white light it produces among individual devices and with high productivity, the inventor of the present invention has found out that the aim is achieved by using an ultraviolet light-emitting element and providing a phosphor layer having a blue-light-emitting phosphor and a yellow-light-emitting phosphor mixedly diffused therein, which finding has led to the present invention.

One main feature of the present invention is the use of an ultraviolet light-emitting element as a light-emitting element. In conventional semiconductor light-emitting devices, blue light-emitting elements such as those based on GaN or SiC are used, and thus the peak wavelength of the light they emit varies in a range of about ±10 nm. By contrast, in a semiconductor light-emitting device according to the invention, an ultraviolet light-emitting element is used instead, and the ultraviolet light from this light-emitting element is absorbed by a phosphor, which then emits blue light. In this way, it is possible to reduce variations in the peak wavelength of the emitted blue light to within a range of about ±2 nm.

Another main feature of the present invention is the provision of a phosphor layer having a blue-light-emitting phosphor and a yellow-light-emitting phosphor mixedly diffused therein. In conventional semiconductor light-emitting devices, which use a blue-light-emitting phosphor and a yellow-light-emitting phosphor, these two types of phosphors are diffused separately in different layers, requiring the formation of two separate layers in the fabrication process. By contrast, in a semiconductor light-emitting device according to the invention, two phosphors are mixedly diffused in a single layer, making it possible to achieve higher productivity than with conventional devices.

The blue-light-emitting phosphor used here may be of any type as long as it emits blue light by absorbing ultraviolet light, examples including halophosphate phosphors, aluminate phosphors, and silicate phosphors. Examples of the activator used together include elements such as cerium, europium, manganese, gadolinium, samarium, terbium, tin, chromium, and antimony. Among these, europium is preferred. Preferably, 0.1 to 10 mol % of the activator is added to the phosphor.

The yellow-light-emitting phosphor may be either of a type that absorbs blue light and emits yellow light or of a type that absorbs ultraviolet light and emits yellow light. In the present invention, where the yellow-light-emitting phosphor is used in a mixture with the blue-light-emitting phosphor, a yellow-light-emitting phosphor of the latter type is preferable to achieve higher light emission efficiency. Examples of phosphors that absorb blue light and emit yellow light include organic phosphors such as allyl-sulfonamide/malemine-formaldelyde co-condensed dye and perylene-based phosphors; and inorganic phosphors such as aluminates, phosphates, and silicates. Among these, perylene-based phosphors and YAG-based phosphors are particularly preferred for their long service life. Examples of the activator used together include elements such as cerium, europium, manganese, gadolinium, samarium, terbium, tin, chromium, and antimony. Among these, cerium is preferred. Preferably, 0.1 to 10 mol % of the activator is added to the phosphor. A preferred combination of the phosphor and the activator is YAG and cerium.

On the other hand, examples of phosphors that absorb ultraviolet light and emit yellow light include phosphors such as (La, Ce)(P, Si)O₄ and (Zn, Mg)O. Examples of the activator used together include terbium and zinc.

The content of each phosphor in the phosphor layer is determined appropriately according to the types of the light-emitting element and phosphors used. In general, a preferred range of the content of each phosphor in the phosphor layer is from 1 to 25% by weight.

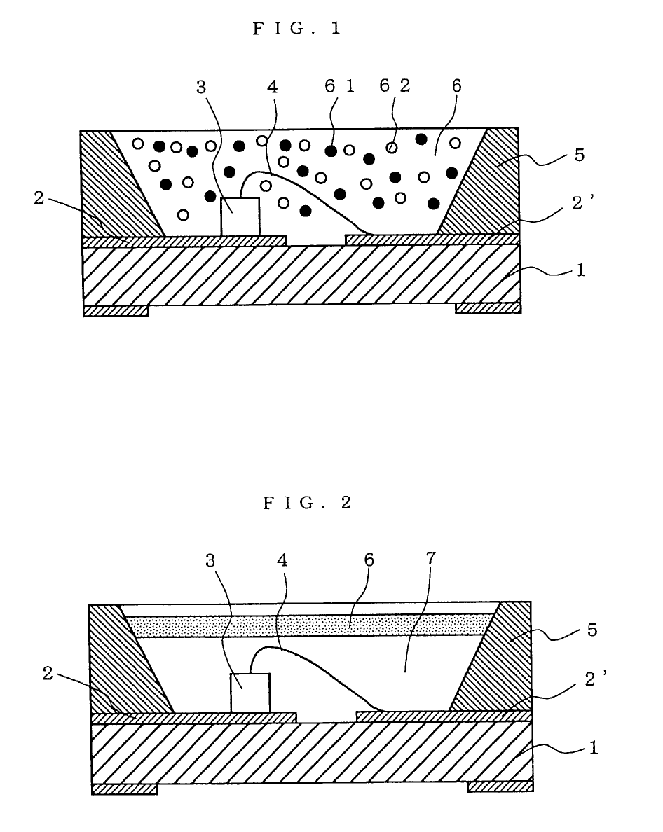

Hereinafter, semiconductor light-emitting devices embodying the present invention will be described with reference to the drawings. It is to be understood, however, that the invention is not limited in any way by these embodiments. FIG. 1 is a sectional view of a chip-type semiconductor light-emitting device according to the invention. On a chip substrate 1, a reflective case 5 is mounted along the edges of the top surface thereof so as to form an enclosure. At both ends of the chip substrate 1, terminal electrodes 2 and 2′ are formed. An ultraviolet light-emitting element 3 is mounted on one terminal electrode 2, and the top-surface electrode (not shown) of the light-emitting element 3 is connected to the other terminal electrode 2′ by a bonding wire 4. The space enclosed by the reflective case 5 is sealed with a phosphor layer 6 having a blue-light-emitting phosphor 61 and a yellow-light-emitting phosphor 62 mixedly diffused therein.

This semiconductor light-emitting device is fabricated, for example, by pouring a thermosetting translucent resin in which two types of phosphors as described above are mixedly diffused beforehand into the reflective case and then curing the resin by application of heat.

In a case where the phosphors 61 and 62 are both of the type that emits light by absorbing ultraviolet light, the semiconductor light-emitting device emits white light by the following mechanism. The ultraviolet light-emitting element 3 emits ultraviolet light, and then the blue-light-emitting and yellow-light emitting phosphors 61 and 62 absorb this ultraviolet light and emit blue and yellow light respectively. Since blue and yellow are complementary colors, the blue and yellow light mix together to permit the semiconductor light-emitting device to emit white light.

On the other hand, in a case where the yellow-light-emitting phosphor 62 is of the type that absorbs blue light and emits yellow light, first, the ultraviolet light emitted from the ultraviolet light-emitting element 3 is absorbed by the blue-light-emitting phosphor 61, which then emits blue light. Next, this blue light is absorbed by the yellow-light-emitting phosphor 62, which then emits yellow light. Then, as in the case described previously, the blue and yellow light mix together to permit the semiconductor light-emitting device to emit white light.

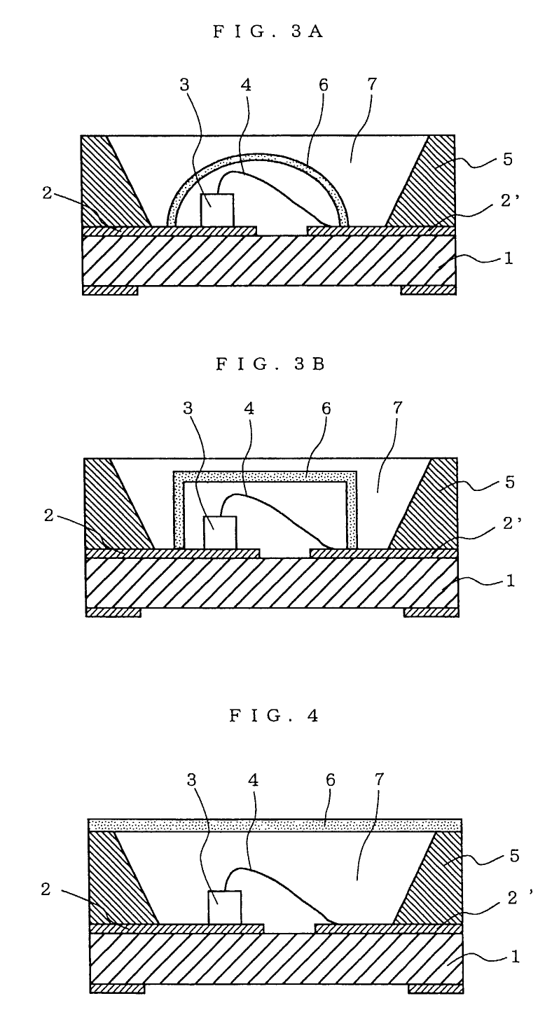

FIG. 2 shows another semiconductor light-emitting device according to the invention. FIG. 2 is a sectional view of the semiconductor light-emitting device, which has the same structure as the device shown in FIG. 1 except for how the phosphor layer 6 is arranged. Specifically, in the semiconductor light-emitting device shown in FIG. 2, a phosphor layer 6 having two types of phosphors mixedly diffused therein is formed inside a sealing member 7 formed out of a translucent resin. In this case, the concentrations of the phosphors contained in the phosphor layer 6 need to be higher than in the device shown in FIG. 1. There is no particular restriction on the position of the phosphor layer 6 inside the sealing member 7; that is, the sealing member 7 may be arranged anywhere between the level of the top surface of the ultraviolet light-emitting element 3 and the level of the surface of the sealing member 7. There is no particular restriction on the shape of the phosphor layer 6, either, as long as all the light emitted from the ultraviolet light-emitting element 3 passes therethrough; for example, the phosphor layer 6 may be shaped like a dome (FIG. 3A) or box (FIG. 3B) so as to enclose the ultraviolet light-emitting element 3.

The semiconductor light-emitting device shown in FIG. 2 is fabricated, for example, in the following manner. A thermosetting translucent resin is poured into the space inside the reflective case 5 up to a predetermined level, and then this resin is cured by application of heat. Next, a thermosetting resin in which two types of phosphors as described earlier are mixedly diffused beforehand is poured on top, and then this resin is cured by application of heat to form a phosphor layer 6. Thereafter, the translucent resin is poured again on top to completely fill the space inside the reflective case 5, and then this resin is cured by application of heat.

FIG. 4 shows another semiconductor light-emitting device according to the present invention. The semiconductor light-emitting device shown in FIG. 4 differs from the semiconductor light-emitting device shown in FIG. 1 in that first a sealing member 7 is formed by filling the space inside the reflective case 5 with a translucent resin and curing it by application of heat and then a phosphor layer 6 is formed all over the surface of the sealing member 7. A phosphor layer 6 like this is formed, for example, by applying to the surface of the sealing member 7 a resin having two types of phosphors as described earlier mixedly diffused therein, or by laying over the surface of the sealing member 7 a sheet having two types of phosphors as described earlier mixedly diffused therein.

All the chip-type semiconductor light-emitting devices described thus far have reflective case 5 mounted on top of a chip substrate 1. However, the present invention applies also to semiconductor light-emitting devices of a so-called mold type, which has no reflective case.

The present invention applies even to lead-type semiconductor light-emitting devices. FIG. 5 shows a lead-type semiconductor light-emitting device in which an ultraviolet light-emitting element 3 is firmly fitted to the bottom of a stem formed in the upper-end surface of a first lead 8 and the top-surface electrode (not shown) of the ultraviolet light-emitting element 3 is connected to the upper end of a second lead 8′ with a bonding wire 4. Here, upper portions of the first and second leads 8 and 8′, the ultraviolet light-emitting element 3, and the bonding wire 4 are sealed in a phosphor layer 6 having a blue-light-emitting phosphor 61 and a yellow-light-emitting phosphor 62 mixedly diffused therein. This semiconductor light-emitting device emits white light by the same mechanism as the chip-type semiconductor light-emitting devices described above.

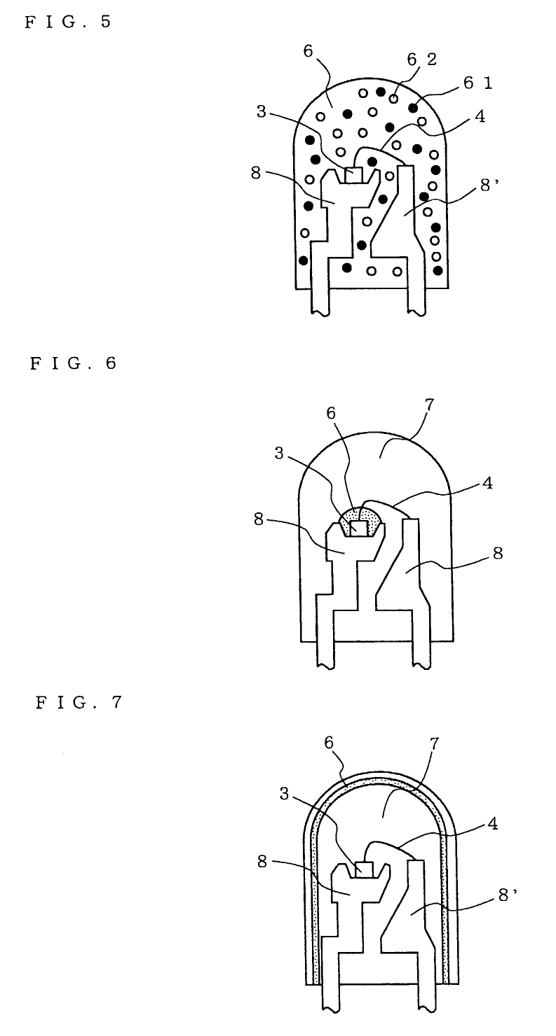

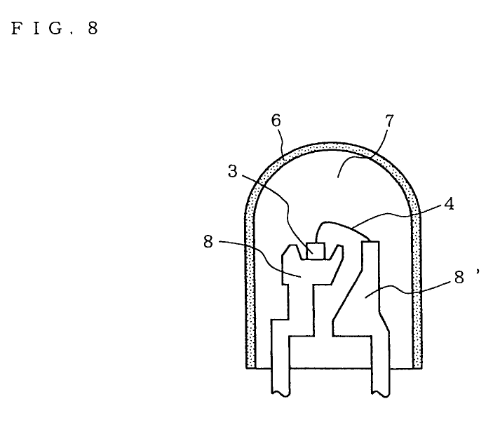

In chip-type semiconductor light-emitting devices like this, there is no particular restriction on the shape of the phosphor layer as long as all the light emitted from the ultraviolet light-emitting element passes therethrough. For example, the phosphor layer 6 may be so formed as to fill the stem to the bottom of which the ultraviolet light-emitting element 3 is firmly fitted (FIG. 6), or may be formed inside a sealing member 7 so as to enclose the ultraviolet light-emitting element 3 (FIG. 7), or may be formed on the surface of a sealing member 7 (FIG. 8). In a case where the phosphor layer 6 is formed as shown in FIG. 8, it may be formed by applying to the surface of the sealing member 7 a resin having two types of phosphors as described earlier mixedly diffused therein, or by molding a resin having two types of phosphors as described earlier mixedly diffused therein into a shape that fits the surface shape of the sealing member 7 and then putting the thus formed molding over the sealing member 7.

What is claimed is:

1. A white semiconductor light-emitting device comprising an ultraviolet light-emitting element and a phosphor layer having a blue-light-emitting phosphor and a yellow-light-emitting phosphor mixedly diffused therein.

2. A white semiconductor light-emitting device as claimed in claim 1, wherein the blue-light-emitting and yellow-light-emitting phosphors are phosphors that absorb ultraviolet light and emit blue and yellow light respectively.

3. A white semiconductor light-emitting device as claimed in claim 1, wherein a content of each of the blue-light-emitting and yellow-light-emitting phosphors in the phosphor layer is in a range of from 1 to 25% by weight of the phosphor layer.

4. A white semiconductor light-emitting device as claimed in claim 1, wherein the phosphor layer is produced by mixedly diffusing the blue-light-emitting and yellow-light-emitting phosphors throughout a translucent resin with which the ultraviolet light-emitting element is sealed.

5. A white semiconductor light-emitting device as claimed in claim 1, wherein the phosphor layer is formed inside a translucent resin with which the ultraviolet light-emitting element is sealed.

6. A white semiconductor light-emitting device as claimed in claim 1, wherein the phosphor layer is formed on a surface of a translucent resin with which the ultraviolet light-emitting element is sealed.
